(19) United States
(12) Patent Application Publication
(10) Pub. No.: US 2007/0281075 A1
(43) Pub. Date: Dec. 6, 2007

(54) Optical method to monitor nano thin-film surface structure and thickness thereof

(76) Inventor: Cheng-Chia Huang, Shanghai (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 11/443,039

(22) Filed: May 31, 2006

(51) Int. Cl. C23C 16/52

(52) U.S. Cl. 427/8

(57) ABSTRACT

A method to monitor a nanocrystalline film surface structure and the thickness thereof uses the surface structure characteristics of the vapor deposition nanocrystalline thin films having the low volume fraction to make a nanocrystalline thin film become a nonhomogeneous double-layer structure comprising a dense bottom layer having high index of refraction and a surface layer having the low volume fraction. The optical module of this double-layer structure can be used to simulate the characteristics of the nanocrystalline structure. That is to say, in the thin film deposition manufacturing process, if the thin film structure satisfies the optical module of the double-layer structure, this means it has the nanocrystalline characteristic. Hence, in the manufacturing process, use the optical instruments to measure the thin film and the substrate and to calculate the optical parameters; thus a nanocrystalline film surface structure and the thickness thereof can be precisely monitored immediately.

### BACKGROUND OF THE INVENTION

1. Field of the Invention

This invention relates to an optical application method, and more particularly to an optical method to monitor a nano thin-film surface structure and the thickness thereof in the nano thin-film deposition manufacturing process.

2. Description of the Prior Art

Nanotechnology has become a very popular topic recently, and it is even considered as one of the most essential technology that has a significant influence on human's future. Nanometer is an adjective of size. The size of nano structures is about 1˜100 nanometers which are between molecule and submicron scale. Therefore, using the classical theory to predict the physical behavior in such a small scale is not proper. The influence of quantum effects will be a non-neglected factor, and further the proportion of the surface area increases a lot. So the physical, chemical and biological properties in such a small scale will be very different from those in a large scale.

Additionally, a nanocrystalline structure has the little size, and it has high roughness and large specific surface area to be used widely in the optronic industry, the semiconductor industry and the optical, energy or environmental industry, such as chemical sensors, low dielectric constant thin films, photonic crystals, LEDs, photo catalysis, memories, and so forth. The modern methods of manufacturing the nano thin-film include the sol-del, wet chemical deposition, vapor deposition, and etc.

The conventional thin-film manufacturing has a high standard in the denseness and planarization. However, a nanocrystalline thin film made by vapor deposition has high roughness, a low volume fraction in the surface specific structure, and a high dense bottom layer. Because this double-layer structure in the thin film manufacturing cannot decide the thin film structure and thickness by non-touch methods, such as the quartz oscillating frequency, split-beam spectrum and polarization ellipse. Consequently, the results of the nanocrystlline thin film have to be waited until the manufacturing process is finished and then are analyzed by the microstructure analysis, such as the electron microscopy. However, this method cannot control the thin film structure and thickness in the deposition manufacturing process immediately. Hence, the quality of the nanocrystalline thin film cannot be controlled, and the failure ratio rises correspondingly.

To solve the aforementioned defects, this invention presents an optical method to monitor a nano thin-film surface structure and the thickness thereof. This invention uses a non-touch detection of the optical transmission spectrum, and has a great help for monitoring the nanocrystalline thin film quality.

### SUMMARY OF THE INVENTION

An object of the present invention is to provide an optical method to monitor a nano thin-film deposition manufacturing process, which simulates the transmittance, reflectance and other optical parameters of a nanocrystalline thin film in the deposition manufacturing process to analyze the structure of the nano thin film, and thus achieves the goal of monitoring the thin-film deposition manufacturing process.

Another objective of the present invention is to provide an optical module, which analyzes the thickness and structure of a nanocrystalline thin film in the deposition manufacturing process to be as a basis of monitoring the manufacturing process.

Further another objective of the present invention is to provide an optical mode simulating nanocrystalline structures, which precisely monitors the surface structure and thickness of a nanocrystalline thin film.

To achieve the abovementioned objectives, the present invention presents a method to measure optical parameters of a transparent substrate through an optical module, and these parameters are as a basis of the thin film deposition condition. In the deposition process, in order to decide what the optical module, the single-layer structure or the double-layer one is adapted by the current thin film. The optical parameters of the thin film substrate are continuously measured by the optical module. Supposing the measured parameters of the thin film are suitable for the single-layer-structure optical module, this means the thin film is a dense structure. After revising the deposition condition, the deposition manufacturing process is continued until the measured parameters of the thin film are suitable for the double-layer-structure optical module, and this means the current thin film is close to a nano thin film surface, which has low volume fraction. Then, judge if the optical parameters of the thin film converge within a range. If they converge, this means the thin film surface has the complete characteristics of low volume fraction and the manufacturing process can be wound up. If they do not converge, this means the manufacturing process is not done yet, and the deposition condition is revised, and then the deposition manufacturing process is continued.

It is to be understood that both the foregoing general description and the following detailed description are exemplary, and are intended to provide further explanation of the invention as claimed.

### BRIEF DESCRIPTION OF THE DRAWINGS

FIG. 1 is an optical path diagram illustrating the light goes through different interfaces.

FIG. 2 is an optical path diagram illustrating the light goes through multilayer homogeneous interfaces.

FIG. 3 is an optical path diagram illustrating the light goes through multilayer nonhomogeneous interfaces.

FIG. 4 is a flow chart illustrating the procedures of the present invention.

FIG. 5 is a flow chart illustrating simulating steps of the single-layer-structure optical module according to the present invention.

FIG. 6 is a flow chart illustrating simulating steps of the double-layer-structure optical module according to the present invention.

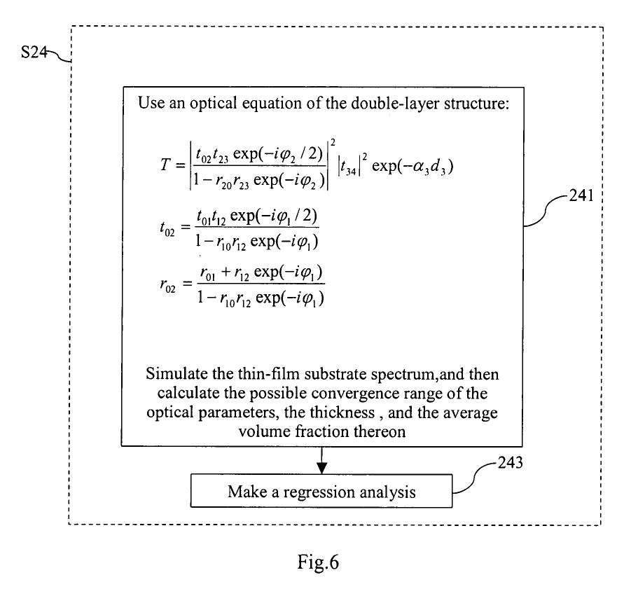

FIG. 7 is a diagram illustrating the analytic results of the optical transmission spectroscopy measurement and the single-layer-dense-structure optical module of a tungsten oxide thin film.

FIG. 8 is a diagram illustrating the analytic results of the optical transmission spectroscopy measurement and the single-layer-dense-structure optical module of a titanium oxide thin film.

FIG. 9 is a diagram illustrating the analytic results of the optical transmission spectroscopy measurement and the single-layer-dense-structure optical module of a stannic oxide thin film.

FIG. 10 is a diagram illustrating the analytic results of the optical transmission spectroscopy measurement and the double-layer-dense-structure optical module of a titanium oxide thin film.

FIG. 11 is a diagram illustrating the analytic results of the optical transmission spectroscopy and the double-layer-dense-structure optical module of a stannic oxide thin film.

FIG. 12 is a diagram illustrating the refractive indexes of titanium oxide and stannic oxide analyzed in the optical module of a nonhomogeneous double-layer structure.

FIG. 13 is a diagram illustrating the results of nanocrystalline surface layer structures of titanium oxide thin films.

### DESCRIPTION OF THE PREFERRED EMBODIMENTS

This invention presents a method to detect a thin-film surface structure and the thickness thereof. Specifically, this invention is to monitor nanocrystalline thin films, wherein the light characteristics such as transmission, reflection, refraction, absorption and so forth, are applied to detect the structure and thickness of thin films.

As for a structure, a nanocrystalline thin film is not a homogeneous single-layer structure, but is a nonhomogeneous single-layer one comprising a dense bottom layer and a high roughness surface structure. If the dense bottom layer and surface structure are taken into account, a nanocrystalline thin film is a nonhomogeneous double-layer structure comprising a low dielectric constant layer with the low volume fraction surface reducing the refractive index and a dense bottom layer with high refractive index. Therefore, utilize the inherent structure of a nano thin film to calculate the thin-film transmittance and the possible convergence range to achieve the goal of monitoring the thin film deposition manufacturing process.

First, when a lightbeam impinges on the interface consisted of different materials, such as the light ray propagating from the air into glass, the lightbeam will be refracted and reflected. The transmittance and reflectance of the interface can be calculated by the below equations:

$$\begin{matrix}interface transmittance {t}_{m , m + 1} = \frac{2 {\tilde{n}}_{m}}{{\tilde{n}}_{m} + {\tilde{n}}_{m + 1}} & ( 1 ) \\ interface reflectance {r}_{m , m + 1} = \frac{{\tilde{n}}_{m} - {\tilde{n}}_{m + 1}}{{\tilde{n}}_{m} + {\tilde{n}}_{m + 1}} & ( 2 )\end{matrix}$$

wherein

t_{m,m+1} is the transmission coefficient of the interface between layers,

r_{m,m+1} is the reflection coefficient of the interface between layers,

ñ is the complex index of refraction (ñ=n−ik),

n is the index of refraction,

k is the extinction coefficient, and

n together with k is called an optical constant of a thin film.

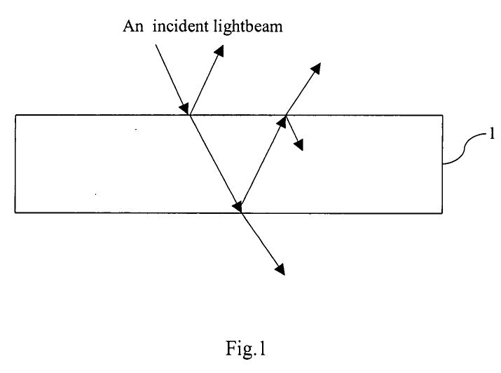

When the lightbeam goes through multilayer interfaces, such as FIG. 1 showing that the lightbeam goes through a thin-film layer 1, the lightbeam forms complex lightbeam groups because of the transmission, reflection and absorption between multilayer interfaces. Further, that the optical path lengths, which at each interface the reflective lightbeams and the refractive lightbeams reach the detector, are different leads the phase shift between the lightbeams. This results in the interference between the lightbeams, and produces the wave motion in the spectrum. The phase shift (φ) at a thin-film interface can be shown as:

$$ϕ = 4 π \tilde{n} d cos \frac{θ}{λ} \qquad ( 3 )$$

wherein

ñd is an optical path,

ñis the complex index of refraction, d is a thin-film thickness,

θ is an incident angle of a lightbeam, and λ is a wavelength of an incident source.

When the lightbeams at the interface are in phase (2ñd cos θ=iλ′ i is an integer), the peaks of the spectrum happen. While they are out of phase

$$( 2 \tilde{n} d cos θ = ( i + \frac{1}{2} ) λ ) ,$$

the valleys of the spectrum happen. Therefore, the thin-film thickness d can be arranged as the below equation:

$$2 d ( \frac{n ( {λ}_{1} )}{{λ}_{1}} - \frac{n ( {λ}_{2} )}{{λ}_{2}} ) cos θ = \frac{1}{2} \qquad ( 4 )$$

wherein

λ₁ is the wavelength between two adjacent peaks, and

λ₂ is the wavelength between two adjacent valleys.

According to the Fresnel theory, a lightbeam goes through multilayer interfaces, and the transmission coefficient and the reflection coefficient at thin-film layer 1 can be calculated from the below equations:

$$\begin{matrix}{t}_{02} = {t}_{01} {t}_{12} exp ( - {iϕ}_{1} / 2 ) \cdot ( 1 + {r}_{12} {r}_{10} exp ( - {iϕ}_{1} ) + … ) = \frac{{t}_{01} {t}_{12} exp ( - {iϕ}_{1} / 2 )}{1 - {r}_{10} {r}_{12} exp ( - {iϕ}_{1} )} & ( 5 ) \\ {r}_{02} = \frac{{r}_{01} + {r}_{12} exp ( - {iϕ}_{1} )}{1 - {r}_{10} {r}_{12} exp ( - {iϕ}_{1} )} & ( 6 )\end{matrix}$$

wherein φ₁ is the phase shift of the thin film, and t₀₁, t₁₂, r₀₁, r₁₂, r₁₀ can be given from the equation (1) and (2). Hence, the transmittance and reflectance of the thin film can be written as

T₀₂=t₀₂· t̅₀₂=|t₀₂|² (7)

R₀₂=r₀₂· r̅₀₂=|r₀₂|² (8)

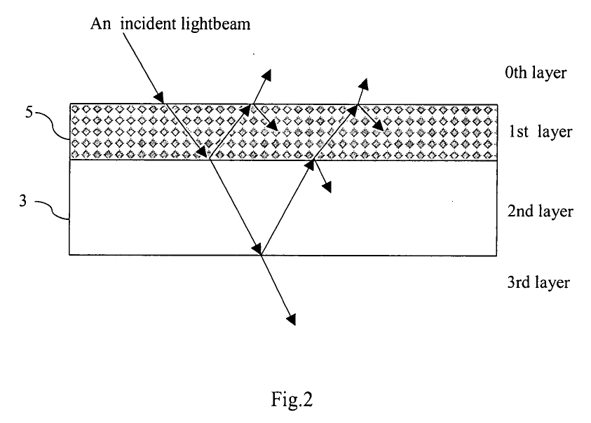

Referring to FIG. 2, a homogeneous thin-film layer 5 is deposited on a transparent substrate 3, and the thickness of this transparent substrate is much bigger than that of the thin film. According to the above optical theory, the transmittance of homogeneous thin-film layer 5 deposited on transparent substrate 3 can be expressed as:

$$T = {\vert \frac{{t}_{01} {t}_{12} exp ( - {iϕ}_{1} / 2 )}{1 - {r}_{10} {r}_{12} exp ( - {iϕ}_{1} )} \vert}^{2} \times \frac{{\vert {t}_{23} \vert}^{2} exp ( - {α}_{2} {d}_{2} )}{1 + {\vert {r}_{02} {r}_{23} \vert}^{2} exp ( - 2 {α}_{2} {d}_{2} )} ; \\ {\vert {r}_{02} {r}_{23} \vert}^{2} exp ( - 2 {α}_{2} {d}_{2} ) -> 0 \qquad ( 9 )$$

wherein
α₂=4πk₂/λ is the absorption coefficient of the substrate, and
d₂ is the thickness of the substrate.

Moreover, if the deposited thin film belongs to a dielectric material having low extinction coefficient, the equation (9) can be simplified as:

$$T = \frac{{t}_{01}^{2} {t}_{12}^{2} {t}_{23}^{2} exp ( - 4 π {k}_{2} {d}_{2} / λ )}{1 - 2 {r}_{10} {r}_{12} cos ( 4 π {n}_{1} {d}_{1} / λ ) + {r}_{10}^{2} {r}_{12}^{2}} \qquad ( 10 )$$

The equation (9) or (10) can be used to simulate the transmission spectrum which the beams pass through the homogeneous thin film and the substrate. The optical constant and the thin-film thickness of the homogeneous thin film can be analyzed by the regress, and the objection function is:

$$obj = {[ \frac{1}{m} {\sum }_{i = 1}^{m} {( \frac{{T}_{i}^{exp .} - {T}_{i}^{cal .}}{{T}_{i}^{exp .}} )}^{2} ]}^{0.5} \qquad ( 11 )$$

wherein
exp. and cal. represent the measurements of the experiments and the simulated results of the theory respectively.

Then, in calculating the values of the optical theory, the transmittance of the dielectric thin film and the extinction coefficient versus the dispersion can be expressed by Cauchy equation (or Sellmeier equation):

$$\begin{matrix}n ( λ ) = {n}_{∞} + \frac{{n}_{1}}{{λ}^{2}} + \frac{{n}_{2}}{{λ}^{4}} + … ; & ( 12 ) \\ k ( λ ) = {k}_{∞} + \frac{{k}_{1}}{{λ}^{2}} + \frac{{k}_{2}}{{λ}^{4}} + … & ( 13 )\end{matrix}$$

n_{∞} and k_{∞} are the transmittance and the extinction coefficients of the infinite wavelength respectively. If the thin film is a semiconductor or a metal material, the relation can be expressed by Kramers-Kronig:

$${ɛ}_{1} ( E ) = {ɛ}_{1} ( ∞ ) + \frac{2 P}{π} {\int }_{0}^{∞} \frac{s {ɛ}_{2} ( s )}{{s}^{2} - {E}^{2}} d s \qquad ( 14 )$$

wherein
for amorphous semiconductors, ∈₂ is

$${ɛ}_{2} ( E ) = {\sum }_{i} \frac{{A}_{i} {C}_{i} {E}_{oi} ( E - {E}_{gi} )}{{( {E}^{2} - {E}_{0 i}^{2} )}^{2} + {C}_{i}^{2} {E}^{2}} \cdot \frac{1}{E}$$

and for crystalline semiconductors, ∈₂ is

$${ɛ}_{2} ( E ) = {\sum }_{i} \frac{{A}_{i}}{{B}_{i} + {( E - {E}_{0 i} )}^{2}}$$

Use multi-variable regression, and d, Aᵢ, Bᵢ, E₀ᵢ, E_{gi} are regression parameters and ∈₁=n²−k², ∈₂=2 nk are dielectric constants.

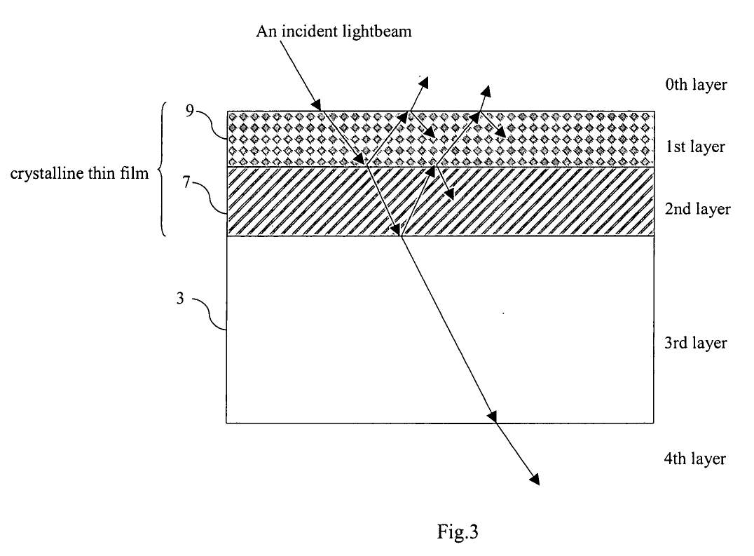

Because a nanocrystalline thin film has a high roughness surface, i.e. it has lower volume fraction to reduce the refractive index and forms a low constant dielectric layer. That is to say, a nanocrystalline thin film is shown as in FIG. 3, and can be regarded as combining a low constant dielectric layer 9 having low refractive index with a dense bottom layer 7 having high refractive index to form a double-layer nonhomogeneous structure. Hence, through an analysis of the optical method, the module of the optical theory can be derived from the equation (9):

$$T = {\vert \frac{{t}_{02} {t}_{23} exp ( - {iϕ}_{2} / 2 )}{1 - {r}_{20} {r}_{23} exp ( - {iϕ}_{2} )} \vert}^{2} {\vert {t}_{34} \vert}^{2} exp ( - {α}_{3} {d}_{3} ) \qquad ( 15 )$$

wherein
ñ₁=(1−f_{d})+ñ₂f_{d} is the complex optical constant of the surface specific structure of the thin film,
f_{d} is the average volume fraction of the thin film at a specific thickness (d₁),
ñ₂ is the complex optical constant of the deposited material, and
φ₁(ñ₁, d₁) is the optical phase shift of the thin-film surface layer
φ₂(ñ₂, d₂) is the optical phase shift of the thin-film bottom layer

The above equations, from the equations (1) to (15), are for the single-layer-structure optical module and the double-layer-structure optical module. In general, the study of the nanocrystalline thin-film manufacturing mostly just uses microstructural analyses of the manufactured components to observe. However, the present invention decides a nanocrystalline thin-film structure in accordance with these two optical modules. This not only can monitor the thin-film thickness of the dense bottom layer of the nanocrystalline thin film, but also analyze the structure and shape of the surface layer having low volume fraction, and further does a great help to the quality control of the nanocrystalline thin-film manufacturing. The following is the concrete interpretation of process procedures.

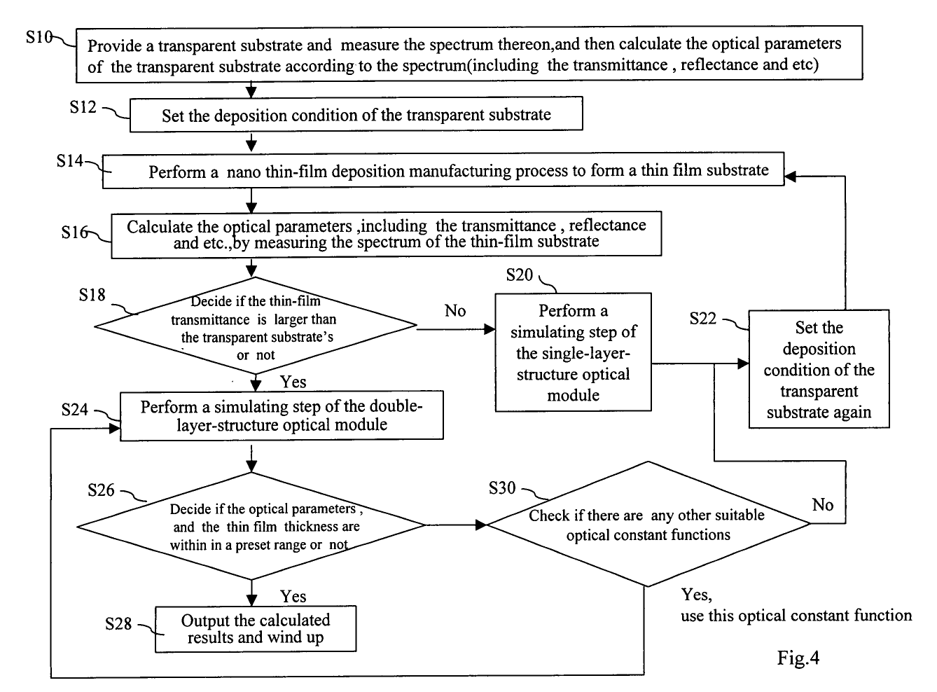

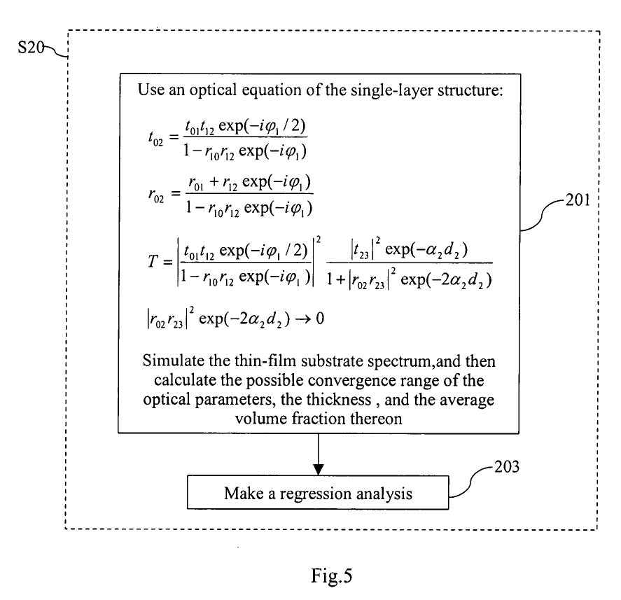

FIG. 4 is a flow chart illustrating the procedures of this method. This invention mainly monitors the thin-film deposition manufacturing process, and consequently the optical equipment is very important for the present invention. The optical equipment can conclude a multi-wavelength light source module, a light intensity detector, a digital-analog signal converter, and so forth. Its monitoring basis is that the transmission and reflective spectrum of the thin film and substrate impinging by the incident beams can be measured in the nano thin-film deposition manufacturing process. In the monitoring method of the present invention, referring to a step S10 first, a transparent substrate is provided, and then an optical module emits a lightbeam to the transparent substrate, and the optical module measures the spectrum of the transparent substrate. Use the abovementioned equations, from the equations (1) to (9), to calculate optical parameters of the transparent substrate, such as the transmittance, reflectance, thickness and so forth. Then, to execute a step S12, the obtained optical parameters of the transparent substrate are the deposition condition of forming nano thin films on the transparent substrate. This will favor the nano thin-film deposition manufacturing process of a step S14 to form a thin-film substrate having a nano thin-film layer. Afterwards, referring to a step S16, equally the optical module is used to measure the spectrum of the transparent substrate to calculate optical parameters of the transparent substrate, such as the transmittance, reflectance, thin-film thickness and so forth. However, a thin-film structure deposited on the transparent substrate will influence an incident lightbeam. When the nano thin film deposited on the transparent substrate is still a dense structure, the reflectance becomes higher. Therefore, the lightbeam transmittance will decrease. When the nano thin film deposited on the transparent substrate is close to a nanocrystalline structure, the low-volume filling ratio of the nano surface layer will make the transmittance decrease and the reflectance incease. Consequently, use this characteristic to continue a step S18, comparing the transmittance of the transparent substrate having a thin film with that of the transparent substrate without any thin film deposited. If the transmittance of the thin-film substrate is smaller than that of the transparent substrate, this means the thin film is still a dense structure and can be regarded as a single-layer structure. Therefore, the simulating step of the single-layer-structure optical module, a step S20, is executed, and is shown in FIG. 5. First, as of a step S201, the single-layer-structure optical equation (the abovementioned equation (9)) is used to simulate the spectrum of the current thin-film substrate, so the possible convergence range of these parameters, like the thin-film transmittance, reflectance, thickness and etc., can be obtained. Then, perform a step S203 to get the optimization regression approaching the optical parameter curve of the thin-film by numerical analysis. Whereas the current thin film does not form a nanocrystalline structure yet, the calculated parameters in the step S20 are used to perform a step S22 in revising the nano thin-film deposition manufacturing process condition, and then a step S14 is performed to continue the nano thin-film deposition manufacturing process. In this invention, the nano thin-film deposition manufacturing process and the optical measurement are performed at the same time, and thus the optical parameters of the thin film can be continuously obtained to be as the basis of the manufacturing revision until the thin film deposited starts to be close the nanocrystalline structure. Owing to the effects of the surface structure, the thin film's current-obtained transmittance will have characteristics against the reflection obviously, and is bigger than the transparent substrate's transmittance. The present thin film can be regarded as a double-layer nonhomogeneous structure comprising a surface layer having low volume filing ratio and a dense bottom layer, i.e. a nanocrystalline structure. So a step S24, a simulating step of the double-layer-structure optical module, can be carried out. In a simulating step of the double-layer-structure optical module, such as a step S241, the abovementioned equation (15) is used to simulate the spectrum of the current thin film substrate. The possible convergence range of these parameters, such as the transmittance, reflectance and thickness of the current thin film, is calculated by the equation (15). Afterwards, perform a step S243 to get the optimization regression approaching the optical parameter curve of the thin-film by numerical analysis. Afterwards, in order to ascertain that the nanocrystalline has reached the preset goal, it is essential to perform a step S26 to judge if the obtained optical parameters of the thin-film substrate by the double-layer-structure optical module are in a preset range or not. The preset range is set in advance according to the desired thin-film condition. If the obtained optical parameters of the thin-film substrate are in the preset range, this means the thin film deposition has reached the preset demands. Then, output the optical parameters of the current thin film and wind up the nano thin-film deposition manufacturing, such as illustrated in a step S28. If the obtained optical parameters of the thin-film substrate are not in the preset range, a step S30 is performed to check if there are any other suitable optical constant functions making the obtained results of the double-layer-structure optical module converge in the range or not. If there are suitable optical constant functions, they are used to perform the simulating step of the double-layer-structure optical module, the step S24 again, to make the obtained results more close to the preset range. If there are none, this means the nanocrystalline manufacturing process does not finish yet. So the current-obtained optical parameters are used to perform the step S22 revising the thin-film deposition condition again, and then go back to the step S14, and continue the nano thin-film deposition.

This invention simulates the spectrum of the thin film by the single-layer-structure optical module and the double-layer-structure one, which not only immediately calculate the thin film thickness, transmittance, reflectance and other related parameters to be as a basis to decide the thin film structure, but also constantly revise the deposition condition of the nano thin-film manufacturing process to make the nano thin film satisfy the preset result as soon as possible.

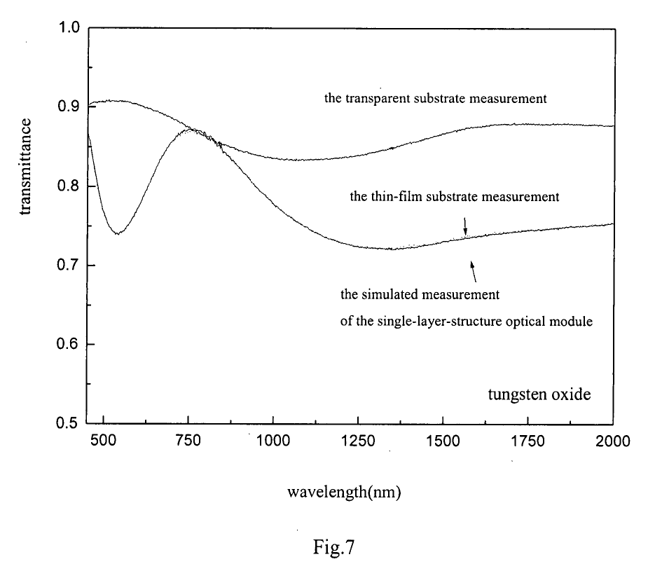

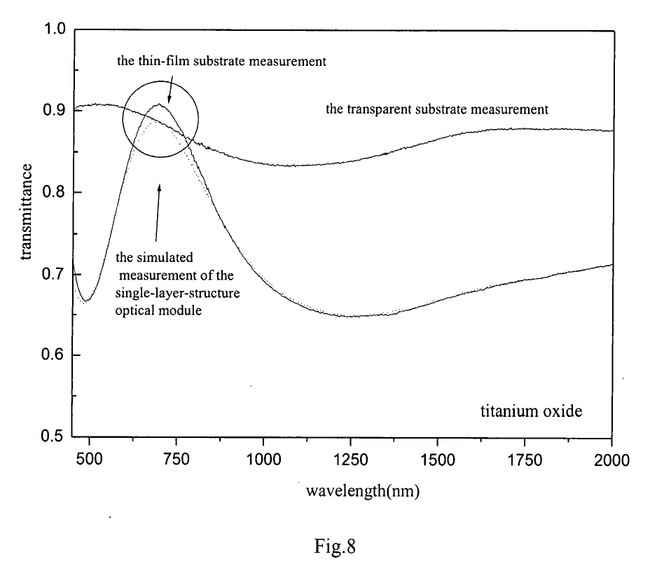

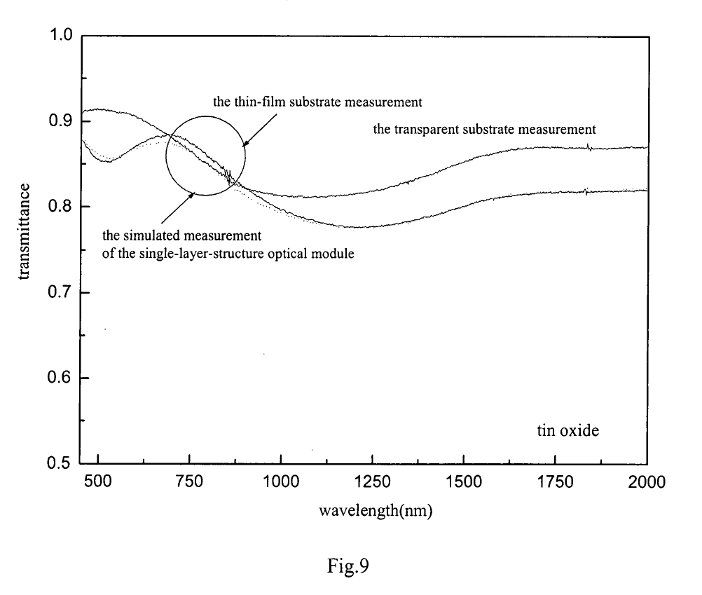

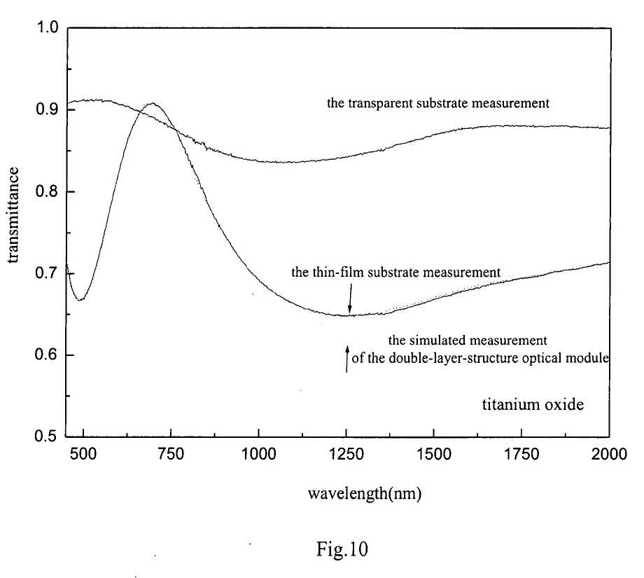

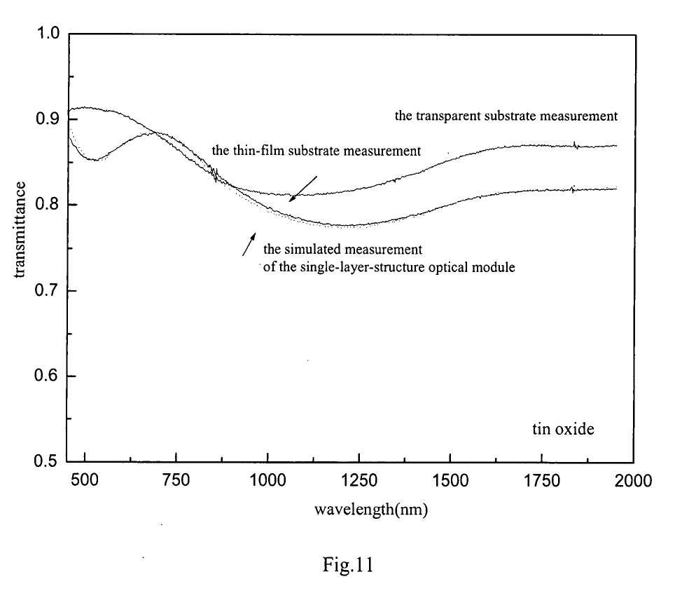

In order to verify this method, the dielectric thin films, like tungsten oxide, titanium oxide, tin oxide and so forth, are respectively deposited on a glass substrate by magnetic plasma sputtering deposition. At some sputtering condition (higher film-coating power and lower deposition speed), a titanium oxide thin film and a tin oxide thin film can be formed into thin films having the characteristics of the nanocyrstalline structure. Hence, a tungsten oxide thin film, a titanium oxide thin film and a tin oxide thin film are deposited on the glass substrate of the respective substrate holders, and the spectrophotometer is used to measure transmission spectrums. The results of a tungsten oxide thin film, a titanium oxide thin film, and a tin oxide thin film analyzed by the single-layer-dense-structure optical module are respectively shown in FIG. 7˜FIG. 9. In FIG. 7, the optical measurement curve is very close to the curve simulated by the single-layer-dense-structure optical module. In FIG. 8 and FIG. 9, however, there is a large variance on regressing the simulated results and the practical measured results by the single-layer-dense-structure optical module. This shows that there is an obvious phenomenon against reflection. Consequently, make a regression analysis on the titanium oxide thin film and tin oxide thin film by the nonhomogeneous double-layer-structure optical module, and the results are shown in FIG. 10 and FIG. 11, illustrating that the simulated curve is very close to the practical one obviously.

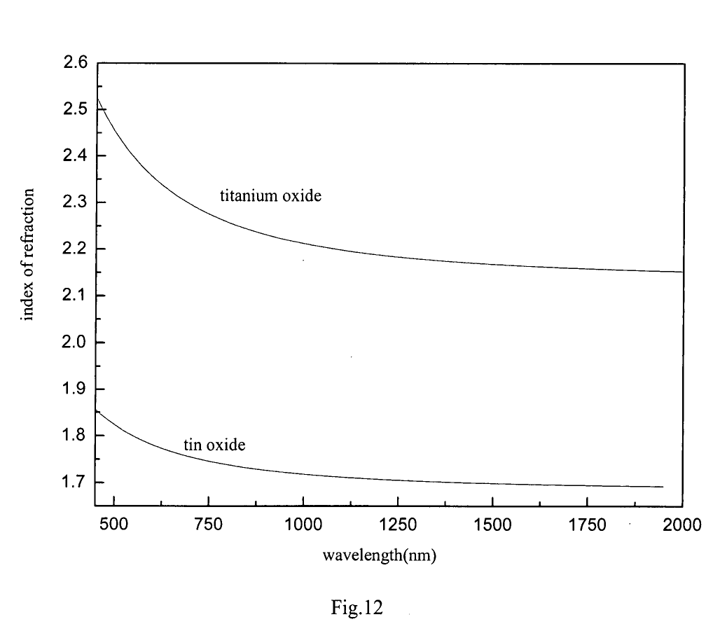

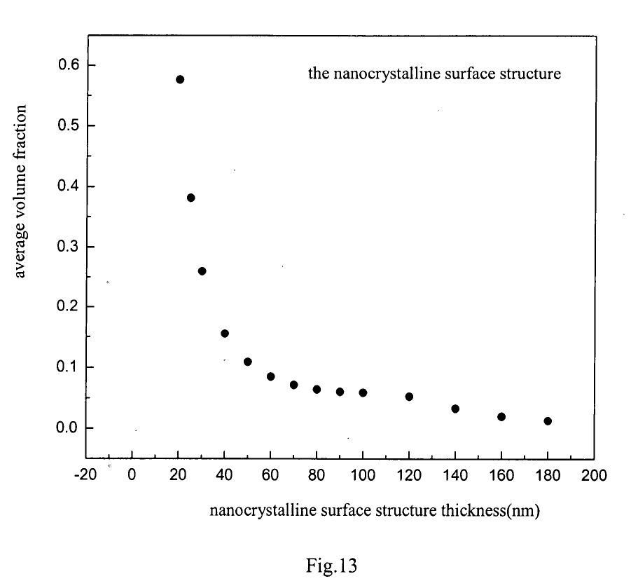

Further, analyze the dense bottom thickness of the titanium oxide thin film and that of the tin oxide thin film. In FIG. 12, which respectively illustrates the refractive index of the titanium oxide thin film and the tin oxide thin film. In FIG. 13, which illustrates the average volume fraction; the nanocrystalline surface structure and shape can be decided by the average volume fraction versus the thickness of the corresponding nanocrystalline surface structure.

The present invention uses the surface structure characteristics of the vapor deposition nanocrystalline thin films having the low volume fraction, and the nano crystalline thin film can be regarded as a nonhomogeneous double-layer structure comprising a high-refractive-index bottom layer and a low-refractive-index surface structure. Further, the optical parameter curve, close to the thin film's optical parameter curve, can be simulated by the optical module of the nonomogeneous double-layer structure. This not only revises the thin film deposition manufacturing process, but also monitors the thin film structure and thickness immediately. Therefore, the present invention provides a nice application for the nanocrystalline thin film manufacturing process.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

What is claimed is:

1. An optical method to monitor a nanocrystalline thin-film surface structure And a thickness thereof, comprising the steps of:
providing a transparent substrate, and measuring a spectrum of the transparent substrate to calculate at least one transparent substrate optical parameter of the transparent substrate, and the transparent substrate optical parameter being as a deposition condition basis to set a nano thin-film deposition manufacturing process;
performing the nano thin-film deposition manufacturing process to form a thin film substrate on the transparent substrate; and
deciding if transmittance of the thin-film substrate is larger than that of the transparent substrate or not; if it is not, a simulating step of a single-layer-structure optical module is carried out to set deposition condition of the transparent substrate again and repeat the nano thin-film deposition manufacturing process; if it is, a simulating step of a double-layer-structure optical module is carried out, until at least one result calculated by the double-layer-structure simulating step is within a predetermined range to be output.

2. The optical method to monitor a nanocrystalline thin-film surface structure and a thickness thereof according to claim 1, wherein transparent substrate optical parameters comprises transparent substrate transmittance, reflectance and refractive index.

3. The optical method to monitor a nanocrystalline thin-film surface structure and a thickness thereof according to claim 1, wherein thin film substrate optical parameters of the thin film substrate comprises thin film substrate transmittance, reflectance and refractive index.

4. The optical method to monitor a nanocrystalline thin-film surface structure and a thickness thereof according to claim 1, wherein when results calculated by the double-layer-structure optical module are over the predetermined range, check if there is at least one suitable optical function parameter making the results in the predetermined range or not; if there is, the optical function parameter is used to perform the simulating step of the double-layer-structure optical module again; if there is not, the deposition condition of the transparent substrate is adjusted again, and then continue the nano thin-film deposition manufacturing process.

5. The optical method to monitor a nanocrystalline thin-film surface structure and a thickness thereof according to claim 1, wherein the simulating step of the single-layer-structure optical module comprises: using an equation,
$$T = {\vert \frac{{t}_{01} {t}_{12} exp ( - {iϕ}_{1} / 2 )}{1 - {r}_{10} {r}_{12} exp ( - {iϕ}_{1} )} \vert}^{2} \times \frac{{\vert {t}_{23} \vert}^{2} exp ( - {α}_{2} {d}_{2} )}{1 + {\vert {r}_{02} {r}_{23} \vert}^{2} exp ( - 2 {α}_{2} {d}_{2} )} ,$$
to simulate a spectrum of the thin film substrate, wherein T is transmittance of the thin film substrate,
$${t}_{m , m + 1} = \frac{2 {\tilde{n}}_{m}}{{\tilde{n}}_{m} + {\tilde{n}}_{m + 1}}$$
is a transmission coefficient of interface between layers,
$${r}_{m , m + 1} = \frac{{\tilde{n}}_{m} - {\tilde{n}}_{m + 1}}{{\tilde{n}}_{m} + {\tilde{n}}_{m + 1}}$$
is the reflection coefficient of the interface between layers, ñ is a complex index of refraction (ñ=n−ik), n is an index of refraction, k is an extinction coefficient, m is an integer, and
$${t}_{0 \; 2} = \frac{{t}_{01} {t}_{12} exp ( - {iϕ}_{1} / 2 )}{1 - {r}_{10} {r}_{12} exp ( - {iϕ}_{1} )} , {r}_{0 \; 2} = \frac{{r}_{01} + {r}_{12} exp ( - {iϕ}_{1} )}{1 - {r}_{10} {r}_{12} exp ( - {iϕ}_{1} )} , \\ {\vert {r}_{02} {r}_{23} \vert}^{2} exp ( - 2 {α}_{2} {d}_{2} ) -> 0 ;$$
and calculating a possible convergence range of thin film substrate optical parameters and that of thin film thickness again, and making a regression analysis.

6. The optical method to monitor a nanocrystalline thin-film surface structure and a thickness thereof according to claim 1, wherein the simulating step of the double-layer-structure optical module, comprises: using an equation,
$$T = {\vert \frac{{t}_{02} {t}_{23} exp ( - {iϕ}_{2} / 2 )}{1 - {r}_{20} {r}_{23} exp ( - {iϕ}_{2} )} \vert}^{2} {\vert {t}_{34} \vert}^{2} exp ( - {α}_{3} {d}_{3} ) ,$$
to simulate a spectrum of the thin film substrate, wherein T is transmittance of the thin film substrate, ñ=(1−f_{d})+ñ₂f_{d} is a complex optical constant of a surface specific structure of the thin film substrate, f_{d} is an average volume fraction of a thin film surface layer at a specific thickness (d₁), ñ₂ is a complex optical constant of a deposited material, and φ₁(ñ₁,d₁) is an optical phase shift of the thin film surface layer, φ₂(ñ₂, d₂) is an optical phase shift of a thin film bottom layer; and
calculating a possible convergence range of thin film substrate optical parameters, thin film thickness and thin film average volume fraction again, and making a regression analysis.

7. The optical method to monitor a nanocrystalline thin-film surface structure and a thickness thereof according to claim 1, wherein when the thin film substrate, formed by the nano thin film deposition manufacturing process, is a nanocrystalline thin film, a nonhomogeneous double-layer structure comprising a dense structure bottom layer and a low volume fraction bottom layer is determined.

8. The optical method to monitor a nanocrystalline thin-film surface structure and a thickness thereof according to claim 7, wherein when the thin film substrate is formed into the nanocrystalline thin film, transmittance of the thin film substrate is larger than that of the transparent substrate.

9. The optical method to monitor a nanocrystalline thin-film surface structure and a thickness thereof according to claim 1, wherein a thin film thickness can be calculated by an average volume fraction of the thin film substrate.

10. The optical method to monitor a nanocrystalline thin-film surface structure and a thickness thereof according to claim 1, wherein the spectrum of the transparent substrate and a spectrum of the thin film are measured by a multi-wavelength light source module.

11. The optical method to monitor a nanocrystalline thin-film surface structure and a thickness thereof according to claim 1, wherein the spectrum of the transparent substrate and a spectrum of the thin film are measured by a light intensity detector.

12. The optical method to monitor a nanocrystalline thin-film surface structures and a thickness thereof according to claim 1, wherein the spectrum of the transparent substrate and a spectrum of the thin film are measured by a digital-analog signal converter.
